(19) United States
(12) Patent Application Publication
(10) Pub. No.: US 2024/0379843 A1
(43) Pub. Date: Nov. 14, 2024

(54) SEMICONDUCTOR DEVICE AND MANUFACTURING METHOD THEREOF

(71) Applicant: HON HAI PRECISION INDUSTRY CO., LTD., New Taipei City (TW)

(72) Inventors: Yi-Kai HSIAO, New Taipei City (TW); Chia-Lung HUNG, New Taipei City (TW); Hao-Chung KUO, New Taipei City (TW)

(21) Appl. No.: 18/650,097

(22) Filed: Apr. 30, 2024

(30) Foreign Application Priority Data
May 8, 2023 (TW) 112117035

(51) Int. Cl. H01L 29/78; H01L 29/06; H01L 29/66

(52) U.S. Cl. CPC H01L 29/7832; H01L 29/0607; H01L 29/66712; H01L 29/66893; H01L 29/7802

(57) ABSTRACT

A method of forming a semiconductor device includes forming an epitaxial layer on a substrate, forming a hard mask layer on the epitaxial layer, forming a JFET region in the epitaxial layer by using the hard mask layer and removing the hard mask layer, forming a staircase-shaped hard mask stack on the JFET region, forming a well region in the epitaxial layer by using the staircase-shaped hard mask stack, in which a bottom of the JFET region is lower than a bottom of the well region and the bottom of the well region is in contact with the JFET region and a drift region of the epitaxial layer simultaneously, forming a source region in the well region, removing the staircase-shaped hard mask stack, and forming a gate structure on the JFET region.

### RELATED APPLICATIONS

This application claims priority to Taiwan Application Serial Number 112117035, filed May 8, 2023, which is herein incorporated by reference.

### BACKGROUND

### Field of Invention

The present disclosure relates to a semiconductor device and a manufacturing method thereof.

### Description of Related Art

The mainstream structure of power semiconductors is vertical double-diffused metal-oxide-semiconductor field-effect transistor (VDMOSFET). In a VDMOSFET, the breakdown voltage of the transistor is controlled by the ion concentration and the thickness of the epitaxial drift layer, and the current is a function of the channel width. Hence, the transistor is allowed to maintain a high breakdown voltage and a large rated current in a small chip. However, under high-power operations, the on-resistance of power semiconductor components mainly comes from the channel resistance, the junction field-effect transistor (JFET) region, and the thickness of the epitaxial drift layer. The thinner is the drift layer, the smaller the on-resistance is and the lower the breakdown voltage is. As a result, when designing a power semiconductor, there needs to be a trade-off between the on-resistance and the breakdown voltage.

In addition, wide energy gap materials, such as silicon carbide, have also been rapidly researched and developed in recent years. As compared with typical silicon materials, its characteristics have more than ten times higher breakdown electric field strength and more than three times higher thermal conductivity, which make it more suitable for applications in high-voltage operations and high temperatures. Such a high breakdown electric field strength can greatly reduce the area and volume of silicon carbide power components, and the small thickness of epitaxial drift layers makes them have a lower on-resistance. Based on the above, the power components created by using silicon carbide will have the characteristics of high withstand voltage, low on-resistance, and high-speed operation. These power components can be applied to the consumer electronics field with high-voltage, high-power, and high-frequency operations, such as electric vehicles, quick charging, etc.

For the foregoing reason, there is a need to solve the above-mentioned problem by providing a semiconductor device and a manufacturing method thereof.

### SUMMARY

A method of forming a semiconductor device is provided. The method of forming the semiconductor device includes: forming an epitaxial layer on a substrate; forming a hard mask layer on the epitaxial layer; forming a junction field-effect transistor (JFET) region in the epitaxial layer by using the hard mask layer and removing the hard mask layer; forming a staircase-shaped hard mask stack on the JFET region; forming a well region in the epitaxial layer by using the staircase-shaped hard mask stack, a bottom of the JFET region being lower than a bottom of the well region, and the bottom of the well region being in contact with the JFET region and a drift region of the epitaxial layer simultaneously; forming a source region in the well region; removing the staircase-shaped hard mask stack; and forming a gate structure on the JFET region.

In the foregoing, forming the staircase-shaped hard mask stack on the JFET region includes: forming a first hard mask and a second hard mask on the JFET region, the second hard mask being on the first hard mask; and etching back the second hard mask so that the second hard mask is narrower than the first hard mask.

In the foregoing, after the second hard mask is etched back, there is a horizontal distance between a sidewall of the first hard mask and a sidewall of the second hard mask, and the horizontal distance is between 0.2 micrometers (μm) and 0.6 μm.

In the foregoing, when the first hard mask and the second hard mask are formed on the JFET region, a thickness of the first hard mask is between 0.5 μm and 0.7 μm.

In the foregoing, when the first hard mask and the second hard mask are formed on the junction field-effect transistor region, a thickness of the second hard mask is between 0.5 μm and 0.8 μm.

In the foregoing, after the source region is formed in the well region, the staircase-shaped hard mask stack includes a dopant of a first semiconductor type and a dopant of a second semiconductor type, and the first semiconductor type is different from the second semiconductor type.

In the foregoing, the method further includes performing an annealing process on the epitaxial layer after forming the source region.

In the foregoing, the ion doping concentration of the junction field-effect transistor region is higher than that of the drift region.

In the foregoing, there is a boundary between the junction field-effect transistor region and the well region, the boundary has a first part and a second part, the first part is farther from the substrate compared with the second part, the second part shifts from the first part in a horizontal direction, the junction field-effect transistor region is in contact with the first part and the second part of the boundary.

In the foregoing, a width of a top of the junction field-effect transistor region is narrower than the bottom of the junction field-effect transistor region.

The present disclosure provides a semiconductor device. The semiconductor device includes a substrate, an epitaxial layer, and a gate structure. The epitaxial layer is on the substrate. The gate structure is on one surface of the epitaxial layer away from the substrate. The epitaxial layer includes a drift region, a JFET region, and a well region. The drift region is adjacent to the substrate. The JFET region is adjacent to one surface of the drift region away from the substrate. The well region is adjacent to the one surface of the drift region away from the substrate and the JFET region. There is a boundary between the JFET region and the well region. The boundary has a first part and a second part. The first part is farther from the substrate compared with the second part. The second part shifts from the first part in a horizontal direction. The JFET region is in contact with the first part and the second part of the boundary, and a bottom of the JFET region is closer to the substrate compared with a bottom of the well region.

In the foregoing, a width of a top of the JFET region is narrower than the bottom of the JFET region.

In the foregoing, the well region has a bottom corner, and the JFET region covers the bottom corner.

In the foregoing, the epitaxial layer further includes a base region and a source region. The base region is in the well region. The source region is in the well region and adjacent to the base region.

In the foregoing, the well region includes a channel region, the channel region is between the JFET region and the source region, and the channel region is adjacent to the gate structure and the first part of the boundary.

In the foregoing, the gate structure is on the junction field-effect transistor region.

In the foregoing, the gate structure is further on a channel region of the well region, wherein the channel region is between the junction field-effect transistor region and the source region.

In the foregoing, the ion doping concentration of the junction field-effect transistor region is higher than that of the drift region.

In the foregoing, the ion doping concentration of the junction field-effect transistor region is from 1E16 to 5E17/cm³, and the ion doping concentration of the drift region is from 2E15 to 5E16/cm³.

In the foregoing, the semiconductor device further includes a source electrode on the gate structure, and a drain electrode at a bottom of the substrate.

Some embodiments of the present disclosure can form the JET region and the well regions with the staircase-shaped boundaries. As a result, when the current flows from the drift region to the JFET region, the path of the current can gradually become narrower. Under the circumstance that the ion doping concentration of the JFET region is slightly higher than that of the drift region, the on-resistance of the semiconductor device can be reduced and the breakdown voltage of the semiconductor device can be maintained at the same time.

It is to be understood that both the foregoing general description and the following detailed description are by examples, and are intended to provide further explanation of the disclosure as claimed.

### BRIEF DESCRIPTION OF THE DRAWINGS

Aspects of the present disclosure are best understood from the following detailed description when read with the accompanying figures. The accompanying drawings are included to provide a further understanding of the present disclosure, and are incorporated in and constitute a part of this specification. The drawings illustrate embodiments of the present disclosure and, together with the description, serve to explain the principles of the present disclosure.

FIG. 1 to FIG. 16 depict cross-sectional views of a process of manufacturing a semiconductor device according to some embodiments of the present disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

Some embodiments of the present disclosure can form the JET region and the well regions with the staircase-shaped boundaries. As a result, when the current flows from the drift region to the JFET region, the path of the current can gradually become narrower. Under the circumstance that the ion doping concentration of the JFET region is approximately the same, the on-resistance of the semiconductor device can be reduced and the breakdown voltage of the semiconductor device can be maintained at the same time.

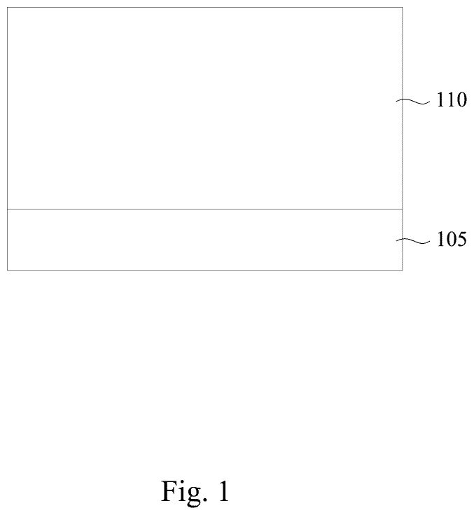

FIG. 1 to FIG. 16 depict cross-sectional views of a process of manufacturing a semiconductor device 100 according to some embodiments of the present disclosure. A description is provided with reference to FIG. 1. An epitaxial layer 110 is formed on a substrate 105. Each of the substrate 105 and the epitaxial layer 110 is any suitable substrate. In some embodiments, the substrate 105 may be made of, for example but not limited to, silicon carbide. A doping agent of a first semiconductor type can be doped into the substrate 105 and the substrate 105 is the first semiconductor type. For example, the substrate 105 may be a heavily doped N-type substrate, for example, a heavily doped region including N-type dopants, such as phosphorus, arsenic, nitrogen, etc. In some embodiments, the epitaxial layer 110 may be made of, for example but not limited to, silicon carbide. The doping agent of the first semiconductor type can be doped into the epitaxial layer 110 and the epitaxial layer 110 is the first semiconductor type. For example, the epitaxial layer 110 may be a lightly doped N-type region, for example, a lightly doped region including N-type dopants, such as phosphorus, arsenic, nitrogen, etc.

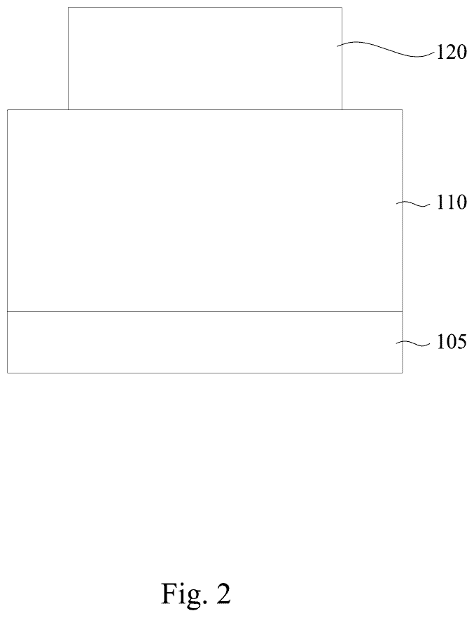

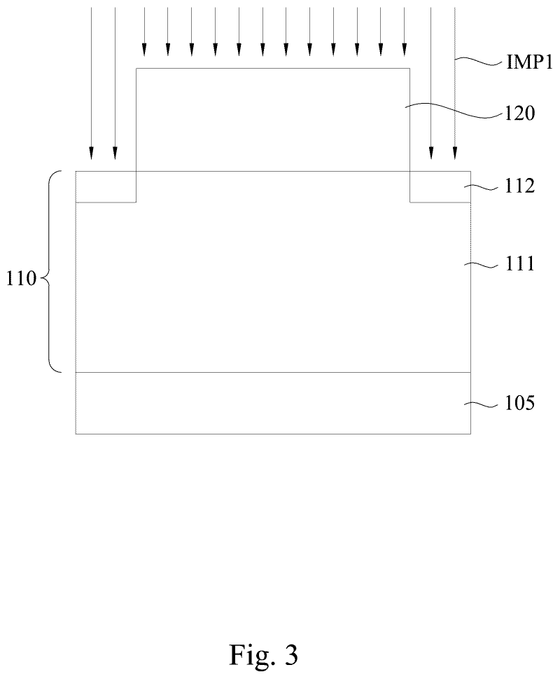

A description is provided with reference to FIG. 2 to FIG. 3. A plurality of base regions 112 are formed in the epitaxial layer 110. In greater detail, a description is provided with reference to FIG. 2. A hard mask layer 120 can be first formed on the epitaxial layer 110. The hard mask layer 120 can expose part of the epitaxial layer 110. Then, a description is provided with reference to FIG. 3. The hard mask layer 120 is used as an ion implantation mask to perform an ion implantation process IMP1, so as to form the base regions 112 in the epitaxial layer 110. In the ion implantation process IMP1, a dopant of a second semiconductor type can be implanted into the epitaxial layer 110, so as to form the base regions 112 of the second semiconductor type in the epitaxial layer 110, and the second semiconductor type is different from the first semiconductor type. For example, the base region 112 may be a heavily doped P-type region, for example, a heavily doped region including P-type dopants, such as boron, aluminum, gallium, etc. Another region of the epitaxial layer 110 not being implanted by ions of the ion implantation process IMP1 is a drift region 111. The hard mask layer 120 can be removed after forming the base regions 112. In some embodiments, the hard mask layer 120 can be removed by using a suitable method, such as etching.

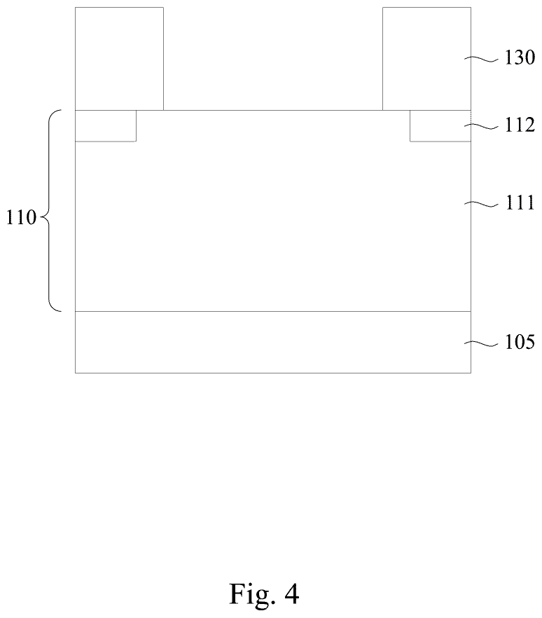

A description is provided with reference to FIG. 4. A hard mask layer 130 is formed on the epitaxial layer 110. The hard mask layer 130 covers the base regions 112 and part of the drift region 111. At the same time, the hard mask layer 130 partially exposes the drift region 111 between the base regions 112.

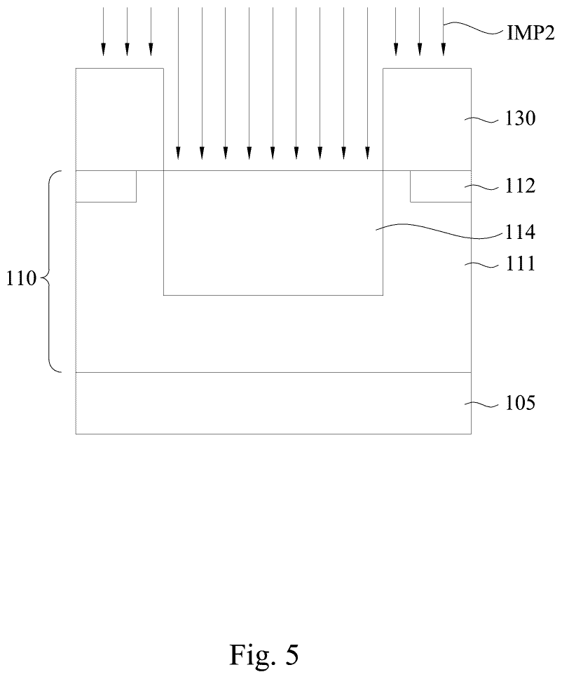

A description is provided with reference to FIG. 5. A junction field-effect transistor (JFET) region 114 is formed in the epitaxial layer 110 by using the hard mask layer 130. In greater detail, the hard mask layer 130 can be used as an ion implantation mask to perform an ion implantation process IMP2, so as to form the JFET region 114 in the epitaxial layer 110. The JFET region 114 may be formed between the two base regions 112, and there is a distance between each of the base regions 112 and the JFET region 114. In the ion implantation process IMP2, the dopant of the first semiconductor type can be implanted into the epitaxial layer 110 so as the form the JFET region 114 of the first semiconductor type in the epitaxial layer 110. For example, the JFET region 114 may be a moderately or lightly doped N-type region, for example, a moderately or lightly doped region including N-type dopants, such as phosphorus, arsenic, nitrogen, etc. The hard mask layer 130 can be removed after forming the JFET region 114. In some embodiments, the hard mask layer 130 can be removed by using a suitable method, such as etching.

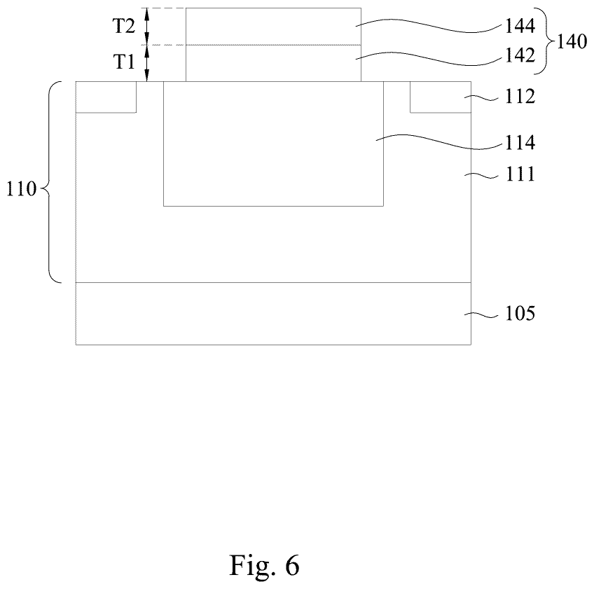

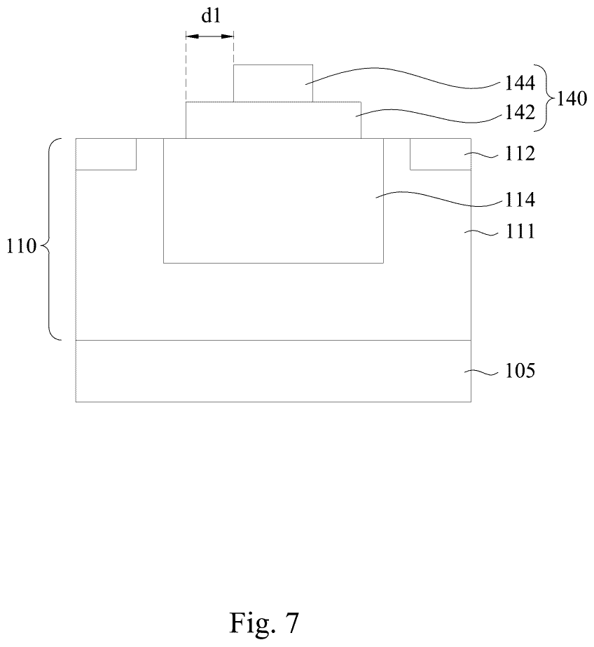

A description is provided with reference to FIG. 6 to FIG. 7. A staircase-shaped hard mask stack 140 is formed on the JFET region 114. In greater detail, a description is provided with reference to FIG. 6. A first hard mask 142 and a second hard mask 144 are formed on the JFET region 114. The second hard mask 144 is on the first hard mask 142. The first hard mask 142 and the second hard mask 144 may be collectively called the hark mask stack 140. The first hard mask 142 and the second hard mask 144 are made of different dielectric materials. For example, the first hard mask 142 may be made of an oxide (such as silicon oxide), and the second hard mask 144 may be made of a nitride (such as silicon nitride). In some embodiments, a first material layer and a second material layer may be sequentially formed on the epitaxial layer 110 first, and the first material layer and the second material layer are patterned by using a photolithography process to form the first hard mask 142 and the second hard mask 144. For example, a photomask may be used to pattern the first material layer and the second material layer, so that sidewalls of the first hard mask 142 and the second hard mask 144 are aligned in a vertical direction. In other words, widths of the first hard mask 142 and the second hard mask 144 in a horizontal direction are substantially equal. The first hard mask 142 and the second hard mask 144 cover a center portion of the JFET region 114 and expose a peripheral portion of the JFET region 114, a portion of the drift region 111, and the base regions 112. A thickness T1 of the first hard mask 142 is between 0.5 micrometers (μm) and 0.7 μm, and a thickness T2 of the second hard mask 144 is between 0.5 μm and 0.8 μm.

A description is provided with reference to FIG. 7. The second hard mask 144 is etched back so that the second hard mask 144 is narrower than the first hard mask 142. Since the second hard mask 144 and the first hard mask 142 are made of different materials, a suitable etchant can be used so that the first hard mask 142 will not be etched when etching the second hard mask 144. In some embodiments, a mask with a smaller width than that of the second hard mask 144 can be formed on the second hard mask 144 first to expose a peripheral region of the second hard mask 144, and then dry etching or wet etching is used to etch back the second hard mask 144. After the second hard mask 144 is etched back, there is a horizontal distance d1 between the sidewall of the first hard mask 142 and the sidewall of the second hard mask 144, and the horizontal distance d1 is between 0.2 μm and 0.6 μm. As a result, the staircase-shaped hard mask stack 140 can be formed. For example, a sidewall of the hard mask stack 140 has a staircase-shaped profile. The horizontal distance d1 can be used to define a channel length in subsequent processes.

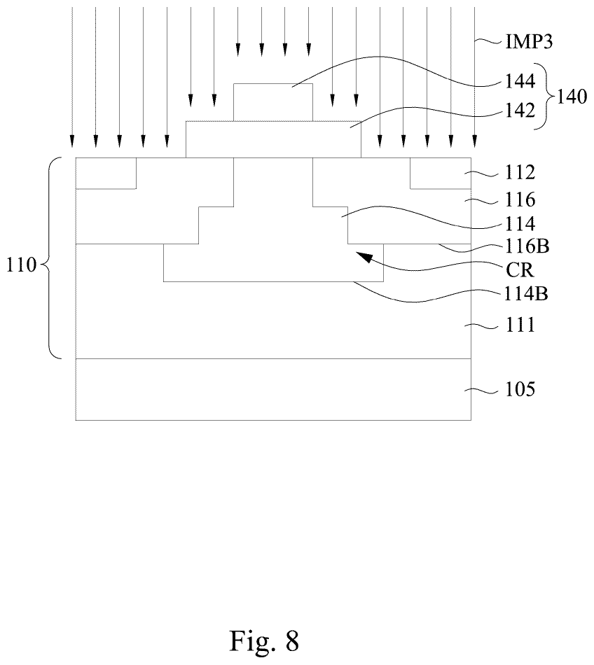

A description is provided with reference to FIG. 8, a plurality of well regions 116 are formed in the epitaxial layer 110 by using the staircase-shaped hard mask stack 140. In greater detail, the staircase-shaped hard mask stack 140 can be used as an ion implantation mask to perform an ion implantation process IMP3, so as to form the well regions 116 in the epitaxial layer 110. In the ion implantation process IMP3, the dopant of the second semiconductor type can be implanted into the epitaxial layer 110, so as to form the well regions 116 of the second semiconductor type in the epitaxial layer 110. For example, each of the well regions 116 may be a lightly to moderately doped P-type region, for example, a lightly to moderately doped region including P-type dopants, such as boron, aluminum, gallium, etc. Since a thickness of the staircase-shaped hard mask stack 140 is not uniform, and an outside portion of the thickness of the staircase-shaped hard mask stack 140 is thinner (that is, only has the first hard mask 142), the implanted ions can enter into the epitaxial layer 110 through the thinner portion of the staircase-shaped hard mask stack 140 when implanting the ions. As a result, ions are not only implanted into regions that are completely not covered by the staircase-shaped hard mask stack 140, but also into regions that are covered by thinner portion of the staircase-shaped hard mask stack 140. Therefore, there is a staircase-shaped boundary between each of the thus formed well regions 116 and the JFET region 114. A bottom of the JFET region 114 is lower than a bottom of each of the well regions 116, and the bottom of each of the well regions 116 is in contact with the JFET region 114 and the drift region 111 of the epitaxial layer 110 simultaneously. That is, each of the well regions 116 has a bottom corner CR, and the JFET region 114 covers the bottom corner CR.

Under the circumstance that the JFET region 114 has this profile, when the semiconductor device 100 operates, a region of the JFET region 114 where a current flows through from a bottom of the substrate 105 (that is, a drain electrode 195 described below) can be widened earlier, and a region where the current flows towards a channel region (that is, a channel region 116C described below) gradually shrinks, rather than shrinks abruptly. Therefore, an on-resistance of the semiconductor device 100 can be reduced. When the thickness T1 of the first hard mask 142 (see FIG. 6), the thickness T2 of the second hard mask 144 (see FIG. 6), and the horizontal distance d1 between the sidewalls of the first hard mask 142 and the second hard mask 144 (see FIG. 7) are within the disclosed ranges, there is a more obvious staircase-shaped boundary between each of the well regions 116 and the JFET region 114. That is, when the semiconductor device 100 operates, the region where the current flows in the JFET region 114 gradually shrinks, thus causing the on-resistance to decrease. If the thickness T1 of the first hard mask 142, the thickness T2 of the second hard mask 144, and the horizontal distance d1 between the sidewalls of the first hard mask 142 and the second hard mask 144 are not within the disclosed ranges, the staircase-shaped boundary between each of the well regions 116 and the JFET region 114 may be not observable, so the region where the current flows through the JFET region 114 can not be widened earlier, and the region where the current flows may shrink abruptly so that the on-resistance can not be reduced. In addition, since an ion doping concentration of the JFET region 114 is slightly higher than an ion doping concentration of the drift region 111, the breakdown voltage does not change much, so this process method can achieve a higher figure of merit (FoM, which can be equal to breakdown voltage²/on-resistance). In some embodiments, the ion doping concentration of the JFET region 114 is from 1E16 to 5E17/cm³, and the ion doping concentration of the drift region 111 is from 2E15 to 5E16/cm³.

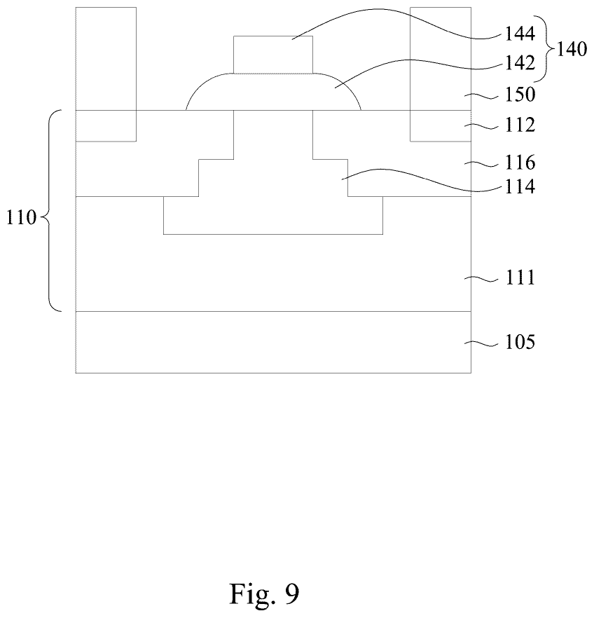

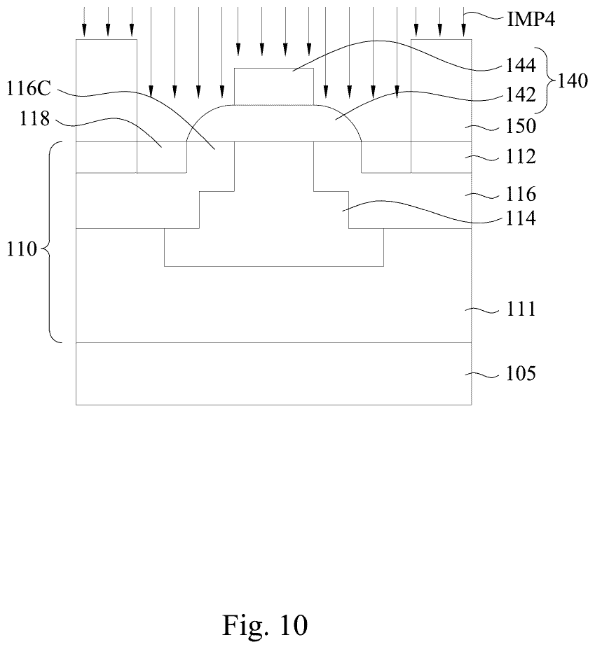

A description is provided with reference to FIG. 9 to FIG. 10. Source regions 118 are formed in the well regions 116. In greater detail, a description is provided with reference to FIG. 9. A hard mask layer 150 may be formed on base regions 112. In some embodiments, a hard mask material layer can be first formed on the epitaxial layer 110 and the staircase-shaped hard mask stack 140, and then the hard mask material layer is patterned to form the hard mask layer 150. During the process of patterning the hard mask layer 150, the first hard mask 142 will also be partially etched to cause that the first hard mask 142 becomes arc-shaped. The hard mask layer 150 and the staircase-shaped hard mask stack 140 expose part of each of the well regions 116.

A description is provided with reference to FIG. 10. The source regions 118 are formed in the well regions 116 by using the hard mask layer 150 and the staircase-shaped hard mask stack 140. In greater detail, the hard mask layer 150 and the staircase-shaped hard mask stack 140 can be used as an ion implantation mask to perform an ion implantation process IMP4, so as to form the source regions 118 in the well regions 116. In the ion implantation process IMP4, the dopant of the first semiconductor type can be implanted into the well regions 116, so as to form the source regions 118 of the first semiconductor type in the well regions 116. For example, the source region 118 may be a heavily doped N-type region, for example, a heavily doped region including N-type dopants, such as phosphorus, arsenic, nitrogen, etc. After the source regions 118 are formed, each of the well regions 116 includes a channel region 116C. The channel region 116C is between the JFET region 114 and the source region 118, and the channel region 116C is on the JFET region 114. After the source regions 118 are formed in the well regions 116, the staircase-shaped hard mask stack 140 includes the dopant of the first semiconductor type and the dopant of the second semiconductor type, and the first semiconductor type is different from the second semiconductor type. In greater detail, since the staircase-shaped hard mask stack 140 is used as the ion implantation masks in the ion implantation process IMP3 of FIG. 8 and the ion implantation process IMP4 of FIG. 10 to define the channel region 116C, the staircase-shaped hard mask stack 140 may include the dopant of the second semiconductor type implanted in the ion implantation process IMP3 and the dopant of the first semiconductor type implanted in the ion implantation process IMP4. As a result, by adjusting the horizontal distance d1 (see FIG. 7) between the sidewalls of the first hard mask 142 and the second hard mask 144 of the staircase-shaped hard mask stack 140, the channel length can be adjusted and the staircase-shaped boundary between the JFET region 114 and each of the well regions 116 is defined.

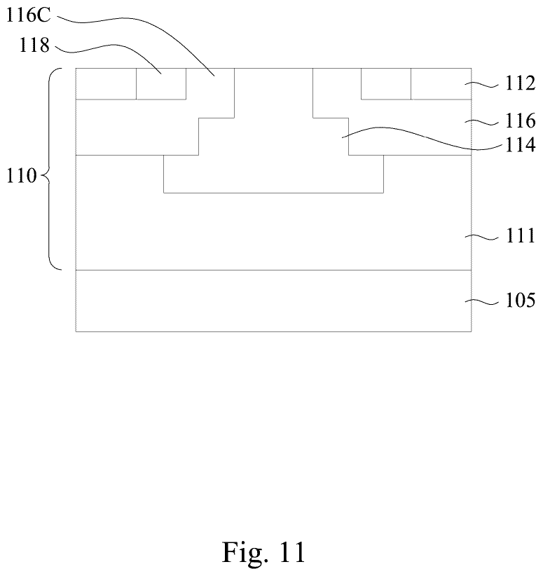

A description is provided with reference to FIG. 11. The hard mask layer 150 and the staircase-shaped hard mask stack 140 are removed, and an annealing process is performed on the epitaxial layer 110. In some embodiments, the hard mask layer 150 and the staircase-shaped hard mask stack 140 can be removed by using a suitable method, such as etching. The annealing process can be used to activate the ions implanted into the epitaxial layer 110, and repair damages caused by the ion implantation processes. In some embodiments, an operating temperature of the annealing process can be between 1600 degrees Celsius (° C.) and 1700° C.

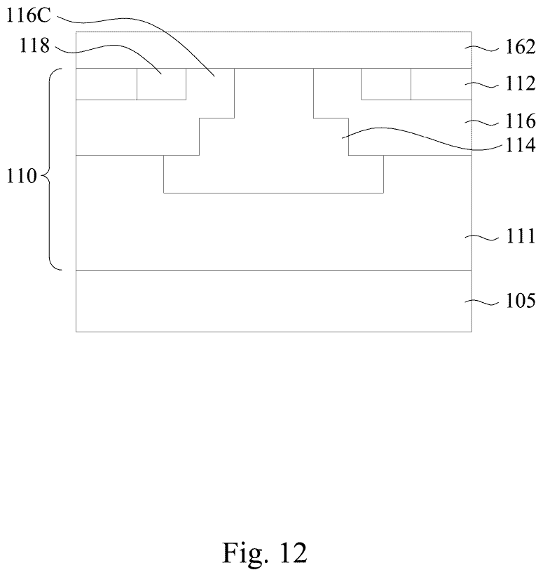

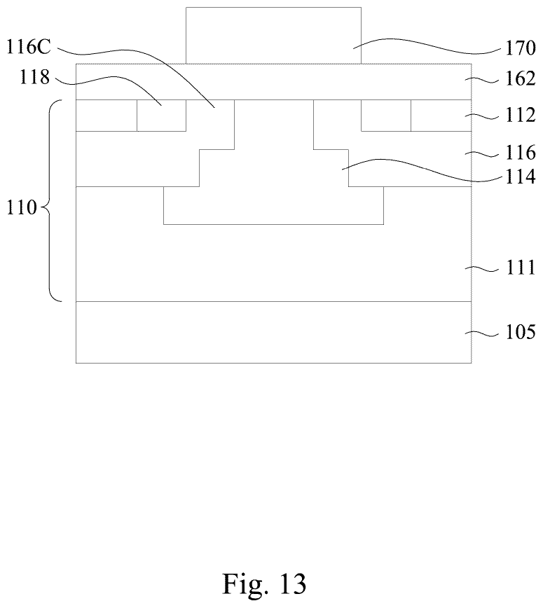

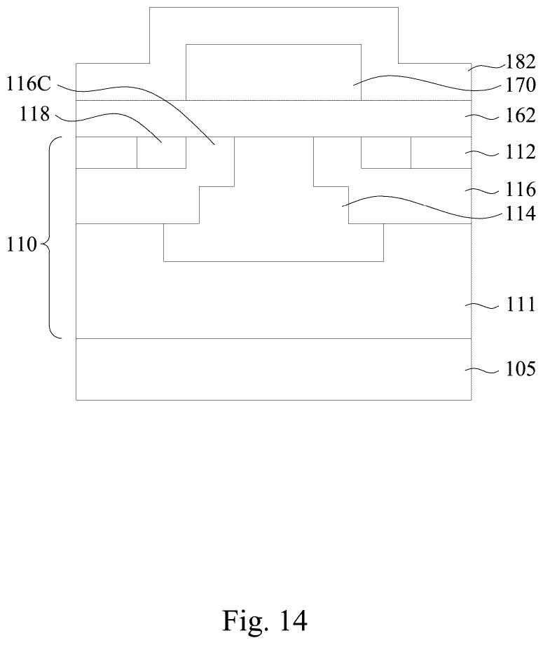

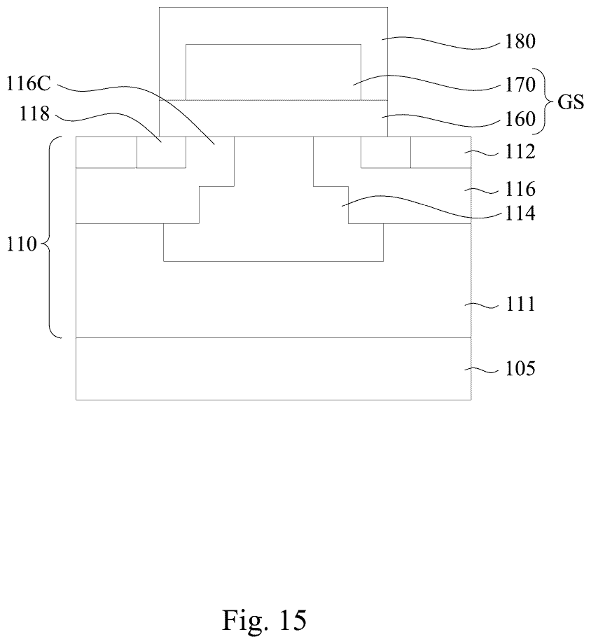

A description is provided with reference to FIG. 12 to FIG. 15. A gate structure GS is formed on the JFET region 114. In greater detail, a description is provided with reference to FIG. 12. A gate dielectric material layer 162 is formed on the epitaxial layer 110. The gate dielectric material layer 162 can be made of any suitable material, such as silicon oxide. Then, a description is provided with reference to FIG. 13. A gate 170 is formed on the gate dielectric material layer 162. The gate 170 can be made of any suitable material, such as polycrystalline silicon. A vertical projection of the gate 170 on the epitaxial layer 110 overlaps the JFET region 114 and the channel regions 116C. After that, a description is provided with reference to FIG. 14. An interlayer dielectric material layer 182 is formed on the gate dielectric material layer 162 and the gate 170. The interlayer dielectric material layer 182 can be made of any suitable material, such as silicon oxide. Next, a description is provided with reference to FIG. 15. The interlayer dielectric material layer 182 and the gate dielectric material layer 162 are patterned to form an inter layer dielectric 180 and a gate dielectric layer 160. Therefore, the gate dielectric layer 160 is on the epitaxial layer 110 and covers the JFET region 114 and the channel regions 116C. The gate 170 is on the gate dielectric layer 160. The inter layer dielectric 180 is on the gate 170 and covers a sidewall and a top surface of the gate 170.

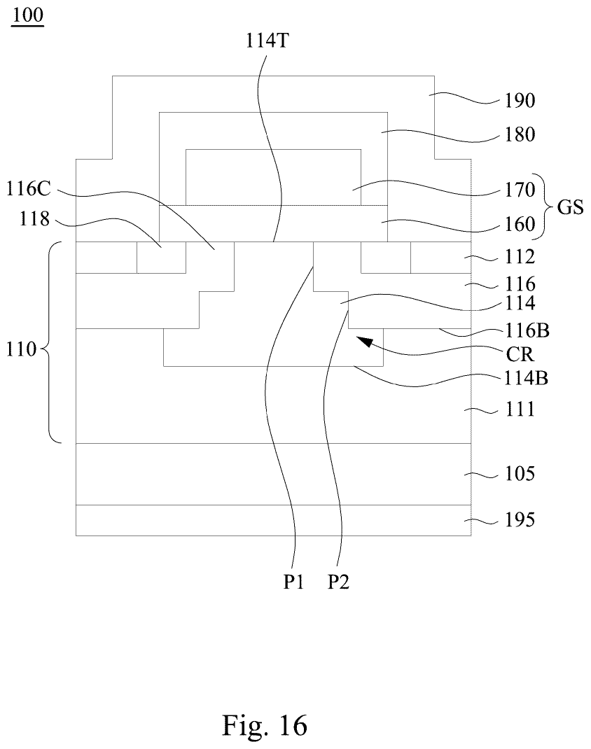

A description is provided with reference to FIG. 16. A source electrode 190 is formed on the epitaxial layer 110 and the inter layer dielectric 180, and the drain electrode 195 is formed at the bottom of the substrate 105. In some embodiments, each of the source electrode 190 and the drain electrode 195 may be made of a conductor, such as a metal, and the metal may be aluminum or other suitable materials. As a result, the semiconductor device 100 can be formed. The semiconductor device 100 includes the substrate 105, the epitaxial layer 110, and the gate structure GS. The epitaxial layer 110 is on the substrate 105, and the epitaxial layer 110 includes the drift region 111, the base regions 112, the JFET region 114, the well regions 116, and the source regions 118. The drift region 111 is adjacent to the substrate 105. The JFET region 114 is on the drift region 111, and is adjacent to one surface of the drift region 111 away from the substrate 105. The well regions 116 are adjacent to the one surface of the drift region 111 away from the substrate 105 and the JFET region 114. There is the staircase-shaped boundary between the JFET region 114 and each of the well regions 116. The staircase-shaped boundary has a first part P1 and a second part of P2. The first part P1 is farther from the substrate 105 compared with the second part P2. The second part P2 shifts from the first part P1 in the horizontal direction. The JFET region 114 is in contact with the first part P1 and the second part P2 of the staircase-shaped boundary, and a bottom 114B of the JFET region 114 is closer to the substrate 105 compared with bottoms 116B of the well regions 116. In some embodiments, the JFET region 114 further covers the bottom corners CR of the well regions 116. The bottom corner CR can be formed by the second part P2 of the staircase-shaped boundary and the bottom 116B of the well region 116. The base regions 112 are in the well regions 116. The source regions 118 are in the well regions 116 and are adjacent to the base regions 112. Each of the well regions 116 includes the channel region 116C. The channel region 116C is adjacent to the gate structure GS and between the JFET region 114 and the source region 118. The channel region 116C is within the first part P1 of the staircase-shaped boundary, so the channel region 116C is adjacent to the gate structure GS and the first part P1 of the staircase-shaped boundary. In some embodiments, the JFET region 114 has a first part, a second part, and a third part. The first part is narrower than the second part, and the second part is narrower than the third part. The first part of the JFET region 114 can be located between the channel regions 116C and is defined by the first parts P1 of the staircase-shaped boundaries. The second part of the JFET region 114 can be defined by the second parts P2 of the staircase-shaped boundaries. The third part of the JFET region 114 can be located below the well regions 116.

The gate structure GS is on the epitaxial layer 110, that is, the gate structure GS is on one surface of the epitaxial layer 110 away from the substrate 105. The gate structure GS may include the gate dielectric layer 160 and the gate 170. The gate dielectric layer 160 is on the epitaxial layer 110 and covers the JFET region 114 and the channel regions 116C. The gate 170 is on the gate dielectric layer 160. The semiconductor device 100 further includes the inter layer dielectric 180, the source electrode 190, and the drain electrode 195. The inter layer dielectric 180 is on the gate 170 and covers the sidewall and the top surface of the gate 170. The source electrode 190 covers the inter layer dielectric 180 and is in contact with the source regions 118 and the base regions 112. The inter layer dielectric 180 provides electrical insulation between the source electrode 190 and the gate 170. The drain electrode 195 is at the bottom of the substrate 105. When the semiconductor device 100 is turned on, the current can flow through the substrate 105, the drift region 111, the JFET region 114 from the drain electrode 195, and then is distributed to the channel regions 116C, source regions 118 on two sides of the JFET region 114, and flows to the source electrode 190. A width of a top 114T of the JFET region 114 is narrower than a bottom 114B of the JFET region 114. Hence, when the current flows from the drift region 111 to the JFET region 114, the path of the current can gradually become narrower rather than become narrower abruptly. As a result, the on-resistance of the semiconductor device 100 can be reduced. Additionally, since the ion doping concentration of the JFET region 114 is slightly higher than that of the drift region 111, the breakdown voltage of the semiconductor device 100 does not change much, so this process method can achieve a higher figure of merit (FoM, which can be equal to breakdown voltage²/on-resistance).

In summary, some embodiments of the present disclosure can form the JFET region and the well regions with the staircase-shaped boundaries. In greater detail, the staircase-shaped hard mask stack can be used as the ion implantation mask to perform the ion implantation process on the epitaxial layer so as to form the JET region and the well regions with the staircase-shaped boundaries. As a result, when the current flows from the drift region to the JFET region, the path of the current can gradually become narrower. Under the circumstance that the ion doping concentration of the JFET region is slightly higher than that of the drift region, the on-resistance of the semiconductor device can be reduced and the breakdown voltage of the semiconductor device can be maintained at the same time.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure covers modifications and variations of this disclosure provided they fall within the scope of the following claims and their equivalents.

What is claimed is:

1. A method of manufacturing a semiconductor device comprising:
forming an epitaxial layer on a substrate;
forming a hard mask layer on the epitaxial layer;
forming a junction field-effect transistor region in the epitaxial layer by using the hard mask layer and removing the hard mask layer;
forming a staircase-shaped hard mask stack on the junction field-effect transistor region;
forming a well region in the epitaxial layer by using the staircase-shaped hard mask stack, a bottom of the junction field-effect transistor region being lower than a bottom of the well region, and the bottom of the well region being in contact with the junction field-effect transistor region and a drift region of the epitaxial layer simultaneously;
forming a source region in the well region;
removing the staircase-shaped hard mask stack; and
forming a gate structure on the junction field-effect transistor region.

2. The method of claim 1, wherein forming the staircase-shaped hard mask stack on the junction field-effect transistor region comprises:
forming a first hard mask and a second hard mask on the junction field-effect transistor region, the second hard mask being on the first hard mask; and
etching back the second hard mask so that the second hard mask is narrower than the first hard mask.

3. The method of claim 2, wherein after the second hard mask is etched back, there is a horizontal distance between a sidewall of the first hard mask and a sidewall of the second hard mask, and the horizontal distance is between 0.2 μm and 0.6 μm.

4. The method of claim 2, wherein when the first hard mask and the second hard mask are formed on the junction field-effect transistor region, a thickness of the first hard mask is between 0.5 μm and 0.7 μm.

5. The method of claim 2, wherein when the first hard mask and the second hard mask are formed on the junction field-effect transistor region, a thickness of the second hard mask is between 0.5 μm and 0.8 μm.

6. The method of claim 1, wherein after the source region is formed in the well region, the staircase-shaped hard mask stack comprises a dopant of a first semiconductor type and a dopant of a second semiconductor type, and the first semiconductor type is different from the second semiconductor type.

7. The method of claim 1, further comprising:
performing an annealing process on the epitaxial layer after forming the source region.

8. The method of claim 1, wherein an ion doping concentration of the junction field-effect transistor region is higher than that of the drift region.

9. The method of claim 1, wherein there is a boundary between the junction field-effect transistor region and the well region, the boundary has a first part and a second part, the first part is farther from the substrate compared with the second part, the second part shifts from the first part in a horizontal direction, the junction field-effect transistor region is in contact with the first part and the second part of the boundary.

10. The method of claim 1, wherein a width of a top of the junction field-effect transistor region is narrower than the bottom of the junction field-effect transistor region.

11. A semiconductor device comprising:
a substrate;
an epitaxial layer on the substrate; and
a gate structure on one surface of the epitaxial layer away from the substrate;
wherein the epitaxial layer comprises:
a drift region adjacent to the substrate;
a junction field-effect transistor region adjacent to one surface of the drift region away from the substrate; and
a well region adjacent to the one surface of the drift region away from the substrate and the junction field-effect transistor region, wherein there is a boundary between the junction field-effect transistor region and the well region, the boundary has a first part and a second part, the first part is farther from the substrate compared with the second part, the second part shifts from the first part in a horizontal direction, the junction field-effect transistor region is in contact with the first part and the second part of the boundary, and a bottom of the junction field-effect transistor region is closer to the substrate compared with a bottom of the well region.

12. The semiconductor device of claim 11, wherein a width of a top of the junction field-effect transistor region is narrower than the bottom of the junction field-effect transistor region.

13. The semiconductor device of claim 11, wherein the well region has a bottom corner, and the junction field-effect transistor region covers the bottom corner.

14. The semiconductor device of claim 11, wherein the epitaxial layer further comprises:
a base region in the well region; and
a source region in the well region and adjacent to the base region.

15. The semiconductor device of claim 14, wherein the well region comprises a channel region, the channel region is between the junction field-effect transistor region and the source region, and the channel region is adjacent to the gate structure and the first part of the boundary.

16. The semiconductor device of claim 11, wherein the gate structure is on the junction field-effect transistor region.

17. The semiconductor device of claim 16, wherein the gate structure is further on a channel region of the well region.

18. The semiconductor device of claim 11, wherein an ion doping concentration of the junction field-effect transistor region is higher than that of the drift region.

19. The semiconductor device of claim 11, wherein an ion doping concentration of the junction field-effect transistor region is from 1E16 to 5E17/cm³, and the ion doping concentration of the drift region is from 2E15 to 5E16/cm³.

20. The semiconductor device of claim 11, further comprising:
a source electrode on the gate structure; and
a drain electrode at a bottom of the substrate.
